(19) United States
(12) Patent Application Publication
(10) Pub. No.: US 2024/0357848 A1
(43) Pub. Date: Oct. 24, 2024

(54) QUANTUM DOT MATERIAL, LIGHT-EMITTING DEVICE, DISPLAY APPARATUS, AND MANUFACTURING METHOD

(71) Applicants: Beijing BOE Technology Development Co., Ltd., Beijing (CN); BOE Technology Group Co., Ltd., Beijing (CN)

(72) Inventor: Wenhai MEI, Beijing (CN)

(21) Appl. No.: 18/578,666

(22) PCT Filed: Jul. 1, 2022
(86) PCT No.: PCT/CN2022/103471

§ 371 Date: Jan. 11, 2024

(30) Foreign Application Priority Data
Jul. 29, 2021 (CN) 202110864258.6

(51) Int. Cl. H10K 50/115; C07B 59/00; C09K 11/02; C09K 11/06; C09K 11/58; C09K 11/60; H10K 50/15; H10K 101/30

(52) U.S. Cl. CPC H10K 50/115; C07B 59/004; C09K 11/02; C09K 11/06; C09K 11/58; C09K 11/60; H10K 50/15; C09K 2211/1007; H10K 2101/30

(57) ABSTRACT

Provided are a quantum dot material, a light-emitting device, a display apparatus, and a manufacturing method. The quantum dot material includes: a plurality of quantum dot bodies, a first ligand, and a second ligand. The first ligand is connected to the quantum dot body and includes: a first coordination group connected to the quantum dot body, a first connection structure, and a first coupling reaction structure. The first connection structure connected the first coordination group and with the first coupling reaction structure. The first coupling reaction structure includes a halide. The second ligand is connected to the quantum dot body and includes: a second coordination group connected to the quantum dot body, a second connection structure, and a second coupling reaction structure. The second connection structure connects the second coordination group with the second coupling reaction structure.

### CROSS-REFERENCE TO RELATED APPLICATIONS

The present application is a National Stage of International Application No. PCT/CN2022/103471, filed Jul. 1, 2022, which claims priority to Chinese patent application No. 202110864258.6, filed with the China National Intellectual Property Administration on Jul. 29, 2021 and entitled “Quantum Dot Material, Light-Emitting Device, Display Apparatus and Manufacturing Method”, the entire contents of which are incorporated herein by reference.

### TECHNICAL FIELD

The present disclosure relates to the technical field of semiconductors, in particular to a quantum dot material, a light-emitting device, a display apparatus, and a manufacturing method.

### BACKGROUND

Quantum dots (QDs) may be referred to as semiconductor nanocrystals, are nanocrystalline particles having a radius smaller than or close to a Bohr exciton radius, and generally have a particle size of 1-20 nm. The quantum dots have a quantum confinement effect and can emit fluorescence after being excited. Moreover, the quantum dots have unique luminescence characteristics such as a wide excitation peak, a narrow emission peak, and an adjustable luminescent spectrum, so that the quantum dots have broad application prospects in the field of photoelectroluminescence. A quantum dot light emitting device (QLED) is a device manufactured by using colloidal quantum dots as a light-emitting layer and adopting a sandwich structure, i.e., a light-emitting layer is introduced between different conductive materials to obtain light of a desired wavelength. The QLED has the advantages of high color gamut, self-luminescence, low starting voltage, fast response speed and the like. In the selection of luminescent quantum dot materials, perovskite quantum dots, indium phosphide quantum dots and the like are becoming a very hot research direction because of high toxicity of cadmium-based quantum dots.

### SUMMARY

Embodiments of the present disclosure provide a quantum dot material, a light-emitting device, a display apparatus, and a manufacturing method. The quantum dot material includes: a plurality of quantum dot bodies;

a first ligand, wherein the first ligand is connected to the quantum dot body and includes: a first coordination group connected to the quantum dot body, a first connection structure, and a first coupling reaction structure, the first connection structure connects the first coordination group with the first coupling reaction structure, and the first coupling reaction structure includes a halide; and a second ligand, wherein the second ligand is connected to the quantum dot body and includes: a second coordination group connected to the quantum dot body, a second connection structure, and a second coupling reaction structure, and the second connection structure connects the second coordination group with the second coupling reaction structure.

In possible embodiments, the first coupling reaction structure includes an aromatic halide, and the second coupling reaction structure includes an aromatic halide, an aromatic alkyne, an alternating single bond-double bond structure, an alternating single bond-triple bond structure, or an alternating triple bond-single bond-double bond structure.

In possible embodiments, the first coordination group includes: amino, sulfhydryl, carboxyl, phosphoxy, or hydroxyl; and the second coordination group includes amino, sulfhydryl, carboxyl, phosphoxy, or hydroxyl.

In possible embodiments, the first connection structure includes a linear carbon chain or a branched carbon chain; and the second connection structure includes a linear carbon chain or a branched carbon chain.

In possible embodiments, the first ligand includes one of:

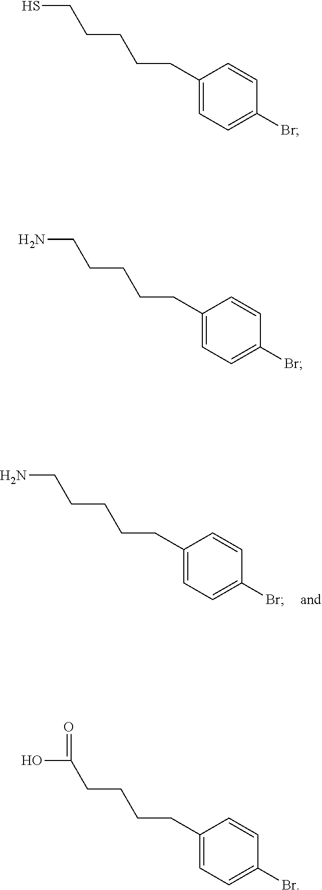 [SMILES: SCCCCCc1ccc(Br)cc1 ; NCCCCCc1ccc(Br)cc1 ; NCCCCCc1ccc(Br)cc1 ; O=C(O)CCCCc1ccc(Br)cc1]

The second ligand includes one of:

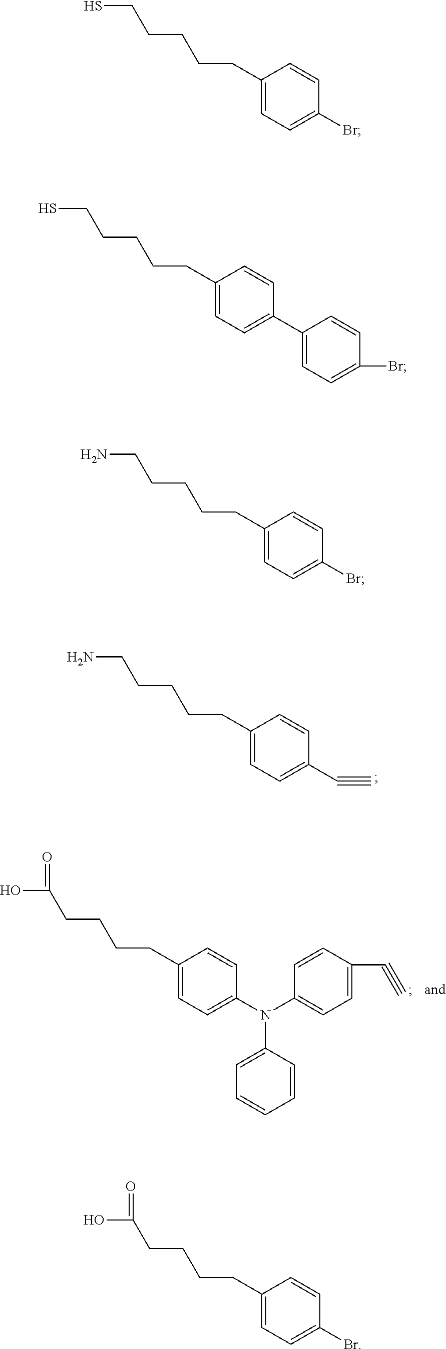 [SMILES: SCCCCCc1ccc(Br)cc1 ; SCCCCCc1ccc(-c2ccc(Br)cc2)cc1 ; NCCCCCc1ccc(Br)cc1 ; C#Cc1ccc(CCCCCN)cc1 ; C#Cc1ccc(N(c2ccccc2)c2ccc(CCCCC(=O)O)cc2)cc1 ; O=C(O)CCCCc1ccc(Br)cc1]

In possible embodiments, the quantum dot body includes a core portion, and a shell layer located on at least part of the surface of the core portion, the shell layer including nickel or copper.

Embodiments of the present disclosure further provide a light-emitting device, including: a base substrate, an anode, a quantum dot layer and a cathode. The anode, the quantum dot layer and the cathode are stacked on one side of the base substrate. The quantum dot layer includes a plurality of quantum dot bodies, and one side, facing the anode layer, of the quantum dot layer is provided with a conjugate.

The conjugate includes: a coupling structure, a first connection structure connected to one side of the coupling structure, a first coordination group being connected to the first connection structure and the quantum dot body, a second connection structure connected to the other side of the coupling structure, and a second coordination group being connected to the second connection structure and the quantum dot body.

In possible embodiments, the coupling structure includes one of:

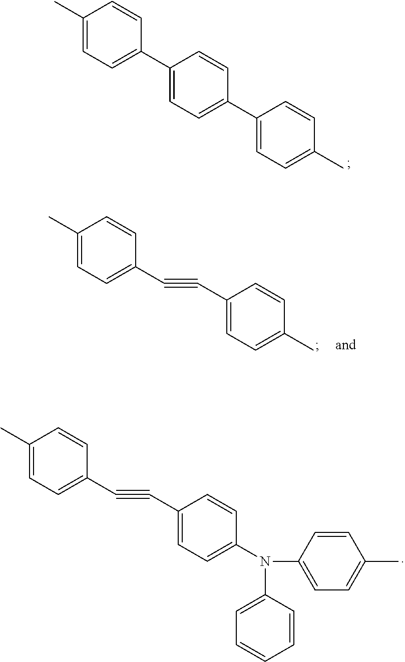

In possible embodiments, the quantum dot layer further includes a first ligand, and in a direction from the anode layer to the quantum dot layer, the content of the conjugate gradually decreases, and the content of the first ligand gradually increases.

In possible embodiments, the quantum dot layer further includes a second ligand, and in the direction from the anode layer to the quantum dot layer, the content of the second ligand gradually increases.

In possible embodiments, a hole transport layer is also disposed between the anode layer and the quantum dot layer; and a HOMO energy level of the conjugate is between a HOMO energy level of the hole transport layer and a HOMO energy level of the quantum dot layer.

In possible embodiments, a material of the hole transport layer includes nickel oxide or tungsten oxide.

Embodiments of the present disclosure further provide a display apparatus, including a plurality of the light-emitting devices provided by the embodiments of the present disclosure.

In possible embodiments, the plurality of the light-emitting devices include different sub-pixel light-emitting devices; and the different sub-pixel light-emitting devices share the same hole transport layer.

In possible embodiments, the conjugates of the different sub-pixel light-emitting devices are different.

Embodiments of the present disclosure further provide a manufacturing method for a quantum dot material, including:
adding quantum dot bodies connected with a native ligand, and a metal ion-containing compound into a first solvent;
carrying out a first reaction to replace the native ligand with the metal ions to obtain quantum dot bodies of which a shell layer includes the metal ions;
dissolving the obtained quantum dot bodies in a second solvent, and adding a first ligand and a second ligand into the second solvent; and

carrying out a second reaction to obtain quantum dot bodies connected with the first ligand and the second ligand.

### BRIEF DESCRIPTION OF FIGURES

FIG. 1 is a first schematic diagram of a quantum dot according to an embodiment of the present disclosure.

FIG. 2 is a second schematic diagram of a quantum dot according to an embodiment of the present disclosure.

FIG. 3 is a third schematic diagram of a quantum dot according to an embodiment of the present disclosure.

FIG. 4 is a fourth schematic diagram of a quantum dot according to an embodiment of the present disclosure.

FIG. 5 is a fifth schematic diagram of a quantum dot according to an embodiment of the present disclosure.

FIG. 6 is a sixth schematic diagram of a quantum dot according to an embodiment of the present disclosure.

FIG. 7 is a seventh schematic diagram of a quantum dot according to an embodiment of the present disclosure.

FIG. 8 is an eighth schematic diagram of a quantum dot according to an embodiment of the present disclosure.

FIG. 9 is a ninth schematic diagram of a quantum dot according to an embodiment of the present disclosure.

FIG. 10 is a schematic diagram of an energy level relationship between the quantum dot and an adjacent film layer according to an embodiment of the present disclosure.

FIG. 11 is a first schematic diagram of a cross-linking reaction of different ligands according to an embodiment of the present disclosure.

FIG. 12 is a second schematic diagram of a cross-linking reaction of different ligands according to an embodiment of the present disclosure.

FIG. 13 is a third schematic diagram of a cross-linking reaction of different ligands according to an embodiment of the present disclosure.

FIG. 14 is a first schematic diagram of a light-emitting device according to an embodiment of the present disclosure.

FIG. 15 is a second schematic diagram of a light-emitting device according to an embodiment of the present disclosure.

FIG. 16 is a third schematic diagram of a light-emitting device according to an embodiment of the present disclosure.

FIG. 17 is a fourth schematic diagram of a light-emitting device provided by an embodiment of the present disclosure.

FIG. 18 is a fifth schematic diagram of a light-emitting device according to an embodiment of the present disclosure.

FIG. 19 is a sixth schematic diagram of a light-emitting device according to an embodiment of the present disclosure.

FIG. 20 is a schematic flow diagram of quantum dot preparation according to an embodiment of the present disclosure.

### DETAILED DESCRIPTION

In order to make the objectives, technical solutions, and advantages of the embodiments of the present disclosure clearer, the technical solutions of the embodiments of the present disclosure will be described clearly and completely below with reference to the accompanying drawings of the embodiments of the present disclosure. Obviously, the described embodiments are a part of the embodiments of the present disclosure, but not all of the embodiments. Based on the described embodiments of the present disclosure, all other embodiments obtained by those of ordinary skill in the art without inventive efforts fall within the scope of protection of the present disclosure.

Unless otherwise defined, the technical or scientific terms used in the present disclosure shall have the ordinary meaning as understood by those of ordinary skill in the art to which the present disclosure belongs. The terms “first,” “second,” and the like as used in the present disclosure do not denote any order, quantity, or importance, but are merely used to distinguish different components. “Include” or “comprise” and other similar words mean that an element or item preceding the word covers elements or items listed behind the word and their equivalents without excluding other elements or items. “Connection” or “connected” and the like are not limited to physical or mechanical connection, but can include electrical connection, whether direct or indirect. “Upper”, “lower”, “left”, “right” and the like are only used for representing a relative position relation, and when an absolute position of the described object is changed, the relative position relation can also be correspondingly changed.

In order to keep the following description of the embodiments of the present disclosure clear and concise, the present disclosure omits detailed descriptions of known functions and known components.

With deep development of a quantum dot technology, the research of electroluminescent quantum dot light-emitting diodes is increasingly deep, the quantum efficiency is continuously improved, which has basically reached the level of industrialization, and further adoption of new processes and technologies to achieve its industrialization has become a trend in the future. At present, an electron transport rate is faster than a hole transport rate in QLED devices, resulting in enrichment of electrons at the interface between a quantum dot layer and a hole transport layer during power-on operation of the devices. On one hand, the enrichment of electrons will cause quantum dots to be charged, and then defects are formed, quenching the quantum dots; on the other hand, the enrichment of electrons can easily generate a large amount of heat at the interface, causing damage to various film layers in the devices. Therefore, how to avoid enrichment of electrons at the interface is a key factor to improve the device performance and service life.

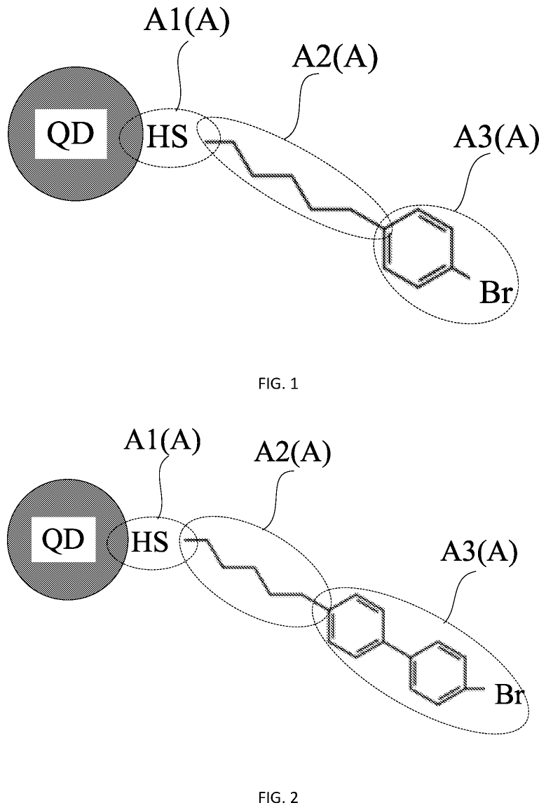

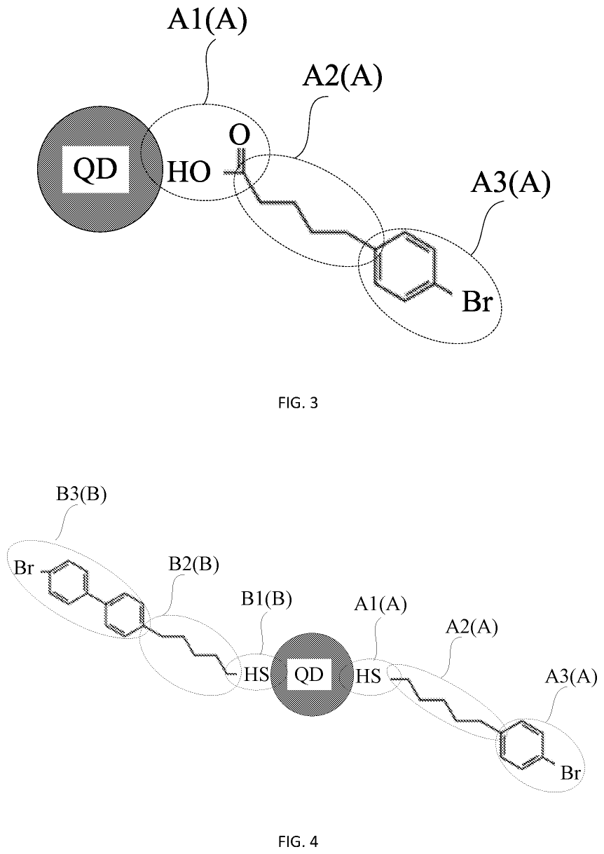

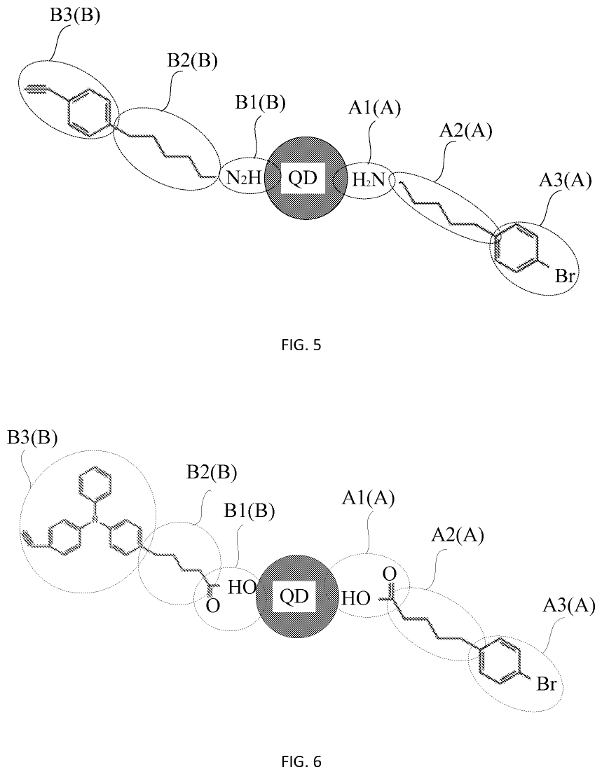

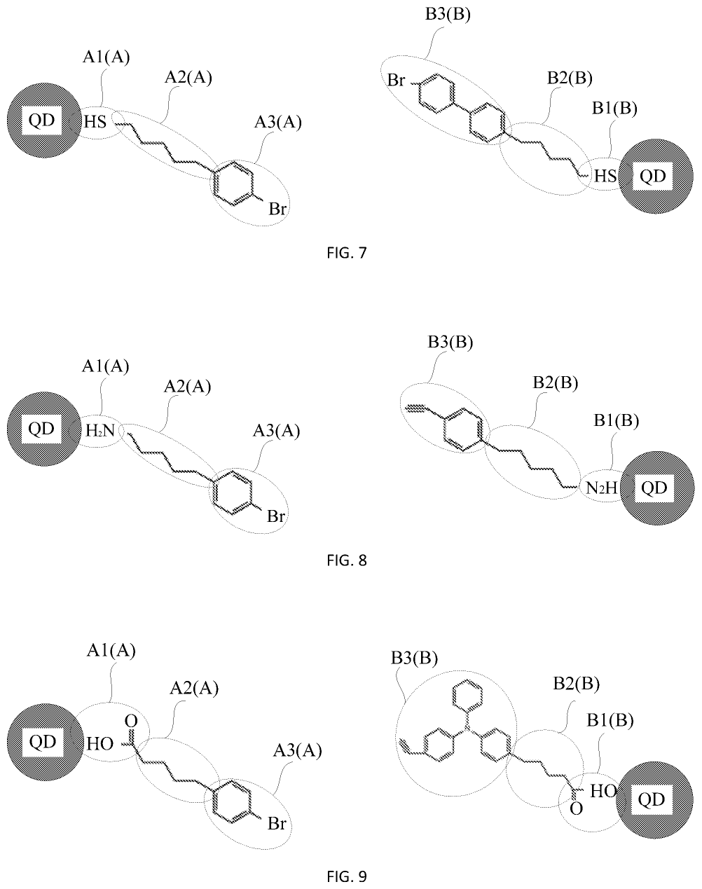

In view of this, with reference to FIG. 1, FIG. 2, FIG. 3, FIG. 4, FIG. 5, FIG. 6, FIG. 7, FIG. 8 and FIG. 9, embodiments of the present disclosure provide a quantum dot, including: a quantum dot body QD;

a first ligand A, wherein the first ligand A is connected to the quantum dot body QD, and includes: a first coordination group A1 connected to the quantum dot body QD, a first connection structure A2, and a first coupling reaction structure A3. The first connection structure A2 connects the first coordination group A1 with the first coupling reaction structure A3, and the first coupling reaction structure A3 includes a halide; and a second ligand B, wherein the second ligand B is connected to the quantum dot body QD, and includes: a second coordination group B1 connected to the quantum dot bodies QDs, a second connection structure B2, and a second coupling reaction structure B3. The second connection structure B2 connects the second coordination group B1 with the second coupling reaction structure B3.

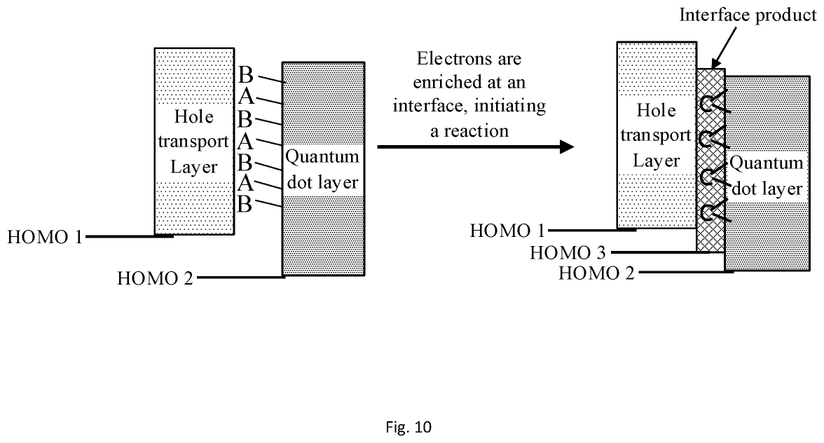

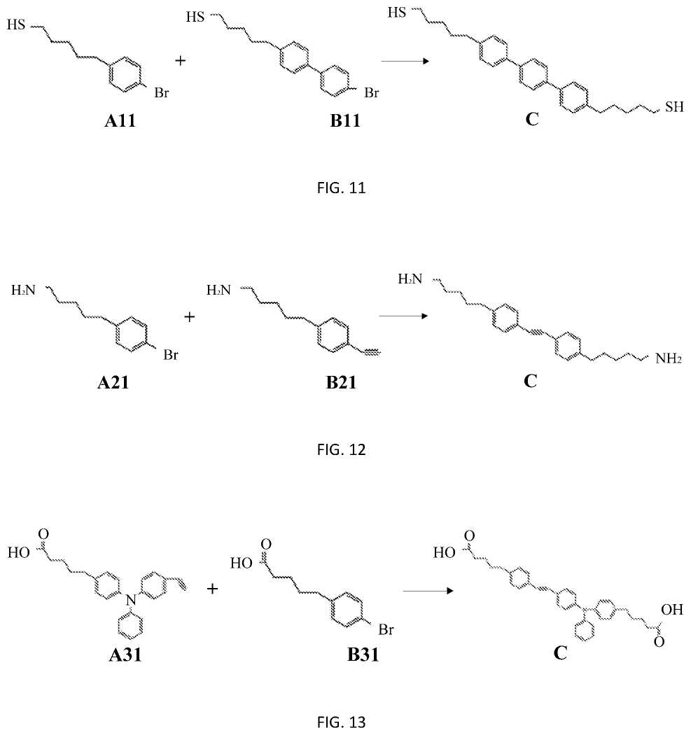

In the embodiments of the present disclosure, the quantum dot body QD is connected with the first ligand A and the second ligand B. The first ligand A includes the first coordination group A1, the first connection structure A2, and the first coupling reaction structure A3. The first coupling reaction structure A3 includes the halide. The second ligand B includes: the second coordination group B1 connected to the quantum dot body QD, the second connection structure B2, and the second coupling reaction structure B3. When the quantum dot is applied to a light-emitting device in which an electron transport rate is faster than a hole transport rate, since electron enrichment occurs on the side, facing an anode layer, of a quantum dot layer (e.g., at the interface between a quantum dot layer and a hole transport layer) during the power-on operation of the light-emitting device to form a donor system, a coupling reaction between the first coupling reaction structure A3 and the second coupling reaction structure B3 at the interface is promoted. The coupling reaction couples at least two ligands together to form a product with a greater conjugation degree at the interface. As shown in FIG. 10, FIG. 11, FIG. 12, and FIG. 13, a HOMO energy level at the interface increases due to the increase of the conjugation degree, playing a role in adding an intermediate barrier on the side, facing the anode layer, of the quantum dot layer (for example, between barriers of the hole transport layer and the quantum dot film layer), thereby facilitating efficient injection of holes into the quantum dot layer and balancing the injection of electrons and holes.

In particular, in the quantum dot material provided by the embodiments of the present disclosure, as shown in FIG. 4, FIG. 5, and FIG. 6, the first ligand A and the second ligand B may be connected to the same quantum dot body QD. Alternatively, as shown in FIG. 7, FIG. 8 and FIG. 9, the first ligand A and the second ligand B may be connected to different quantum dot bodies QDs. Further, the first ligand A and the second ligand B may be the same, i.e., the quantum dot material includes ligands of the same kind, and when the quantum dot material is applied to a light-emitting device, the ligands of the same kind may be self-coupled to be bound together to form a product with a greater degree of conjugation at the interface. Alternatively, the first ligand A and the second ligand B may be different.

In particular, in the embodiments of the present disclosure, the first ligand A is connected to the quantum dot body QD, which can be understood to mean that the first ligand A is connected to the quantum dot body QD by coordination of a coordinate bond. The second ligand B is connected to the quantum dot body QD, which can be understood to mean that the second ligand B is connected to the quantum dot body QD by coordination of a coordinate bond.

In particular, coupling of an aromatic halide and an aromatic halide by an electron transfer reaction may be as follows:

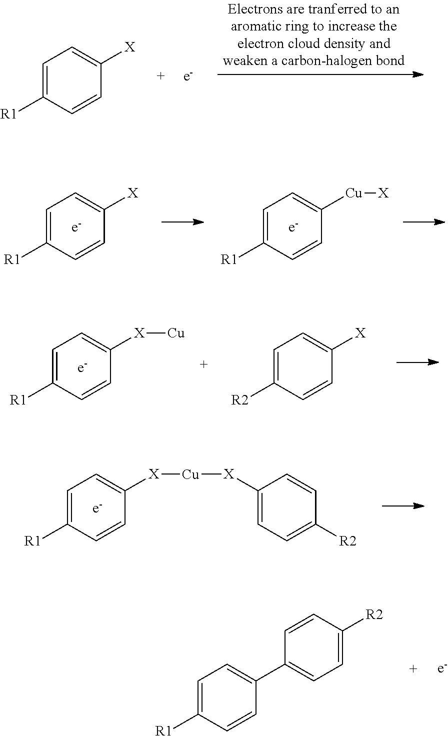

Here, X represents halogen, R1 includes the first coordination group A1 and the first connection structure A2 of the first ligand A, and R2 includes the second coordination group B1 and the second connection structure B2 of the second ligand B. In a multi-electron device structure, electrons are transferred to an aromatic ring to increase the electron cloud density of the aromatic ring and weaken a carbon-halogen bond, and then the first ligand A and the second ligand B are subjected to a coupling reaction under the catalytic action of metal ions (e.g., copper ions), i.e., the aromatic halides are subjected to copper-catalyzed dehalogenation to form coupling of an aromatic ring and an aromatic ring.

In particular, coupling of an aromatic halide and an aromatic alkyne by an electron transfer reaction may be as follows:

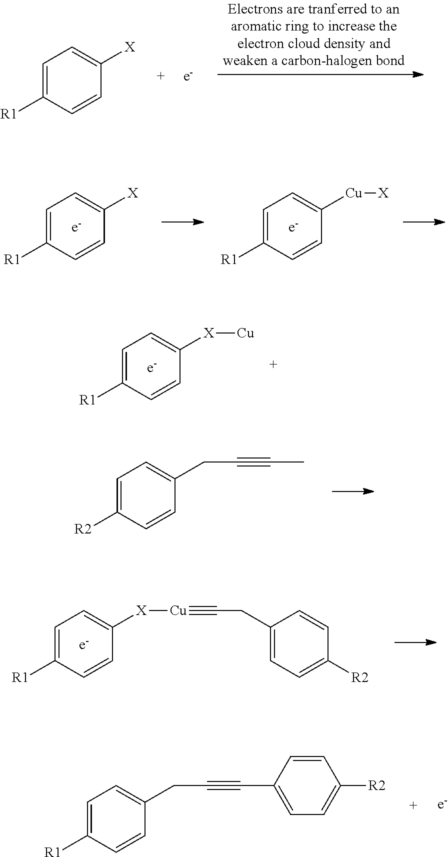

Here, X represents halogen, R1 includes the first coordination group A1 and the first connection structure A2 of the first ligand A, and R2 includes the second coordination group B1 and the second connection structure B2 of the second ligand B. In a multi-electron device structure, electrons are transferred to an aromatic ring to increase the electron cloud density of the aromatic ring and weaken a carbon-halogen bond, and then the first ligand A and the second ligand B are subjected to a coupling reaction under the catalytic action of metal ions (e.g., copper ions), i.e., the aromatic alkyne and the aromatic halide are subjected to a copper-catalyzed reaction to form connection of aromatic rings on both sides by alkyne.

In possible embodiments, the first coupling reaction structure A3 includes an aromatic halide, and the second coupling reaction structure B3 includes an aromatic halide, an aromatic alkyne, an alternating single bond-double bond structure, an alternating single bond-triple bond structure, or an alternating triple bond-single bond-double bond structure.

In particular, the first coupling reaction structure A3 and the second coupling reaction structure B3 can be the same, e.g., both the first coupling reaction structure A3 and the second coupling reaction structure B3 are aromatic halides. In particular, the first coupling reaction structure A3 and the second coupling reaction structure B3 may also be different, e.g., one is an aromatic halide and the other is an aromatic alkyne.

In possible embodiments, the first coordination group A1 includes: amino, sulfhydryl, carboxyl, phosphoxy, or hydroxyl; and the second coordination group B1 includes amino, sulfhydryl, carboxyl, phosphoxy, or hydroxyl. In this way, connection with the quantum dot body QD can be achieved.

In possible embodiments, the first connection structure A2 includes a linear carbon chain or a branched carbon chain; and the second connection structure B2 includes a linear carbon chain or a branched carbon chain.

In possible embodiments, the first ligand A includes one of:

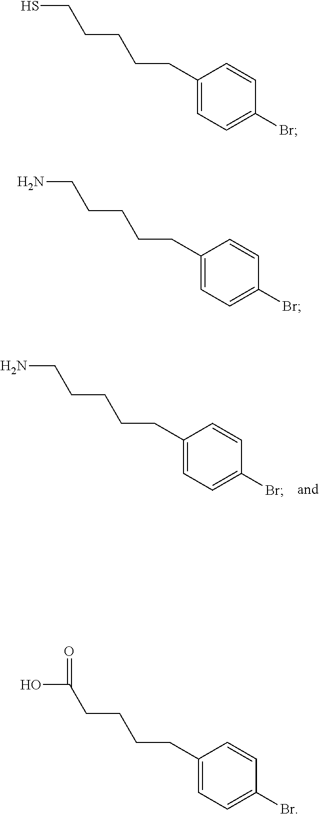 [SMILES: SCCCCCc1ccc(Br)cc1 ; NCCCCCc1ccc(Br)cc1 ; NCCCCCc1ccc(Br)cc1 ; O=C(O)CCCCc1ccc(Br)cc1]

The second ligand includes one of:

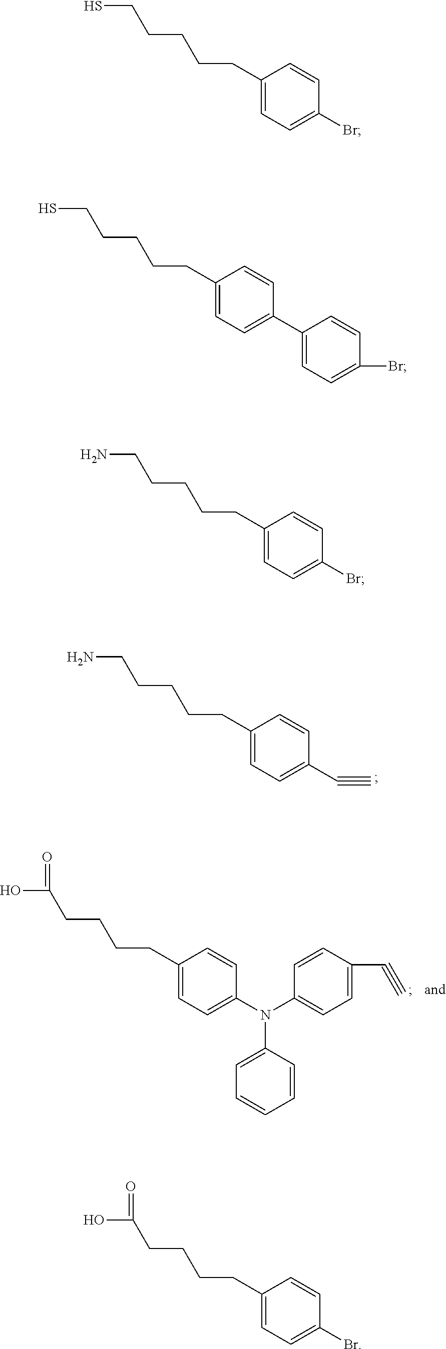 [SMILES: SCCCCCc1ccc(Br)cc1 ; SCCCCCc1ccc(-c2ccc(Br)cc2)cc1 ; NCCCCCc1ccc(Br)cc1 ; C#Cc1ccc(CCCCCN)cc1 ; C#Cc1ccc(N(c2ccccc2)c2ccc(CCCCC(=O)O)cc2)cc1 ; O=C(O)CCCCc1ccc(Br)cc1]

In possible embodiments, the quantum dot body QD includes a core portion, and a shell layer located on at least part of the surface of the core portion. The shell layer includes nickel or copper. In embodiments of the present disclosure, the shell layer of the quantum dot body includes nickel or copper, which can play a catalytic role during the coupling reaction to facilitate the coupling reaction.

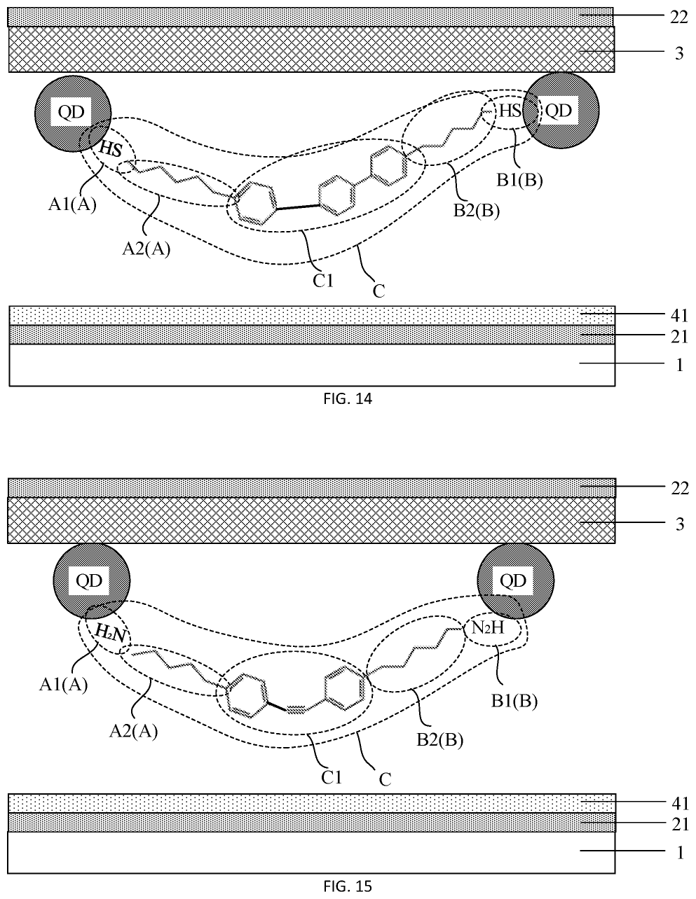

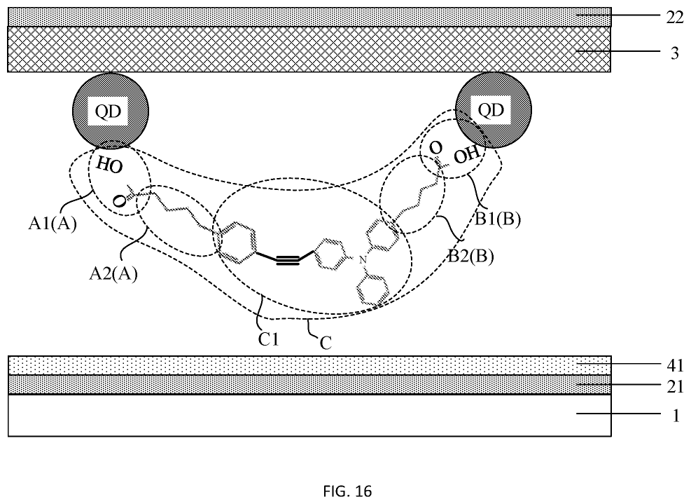

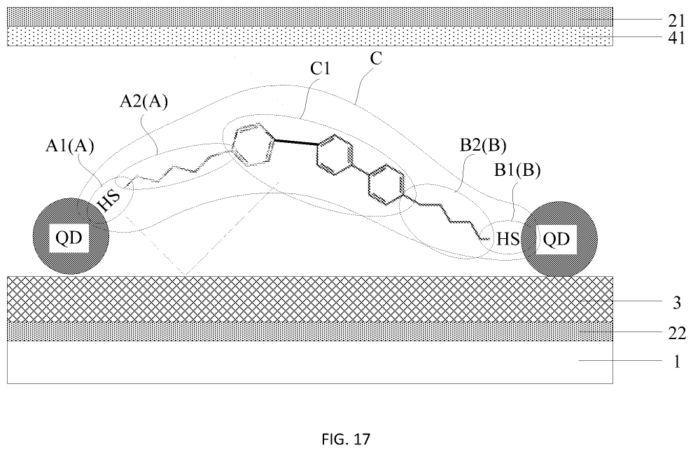

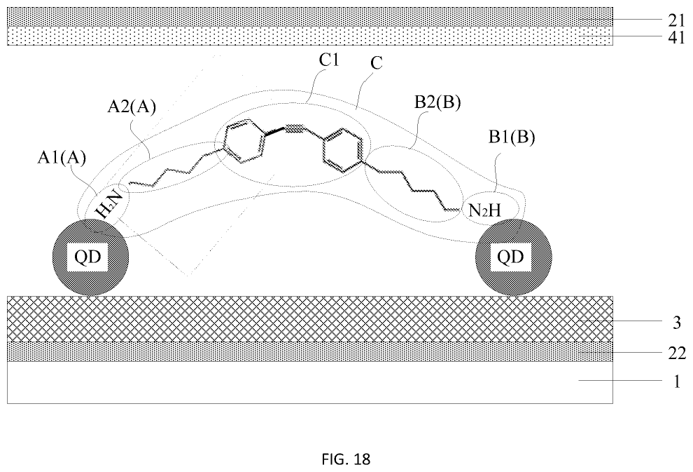

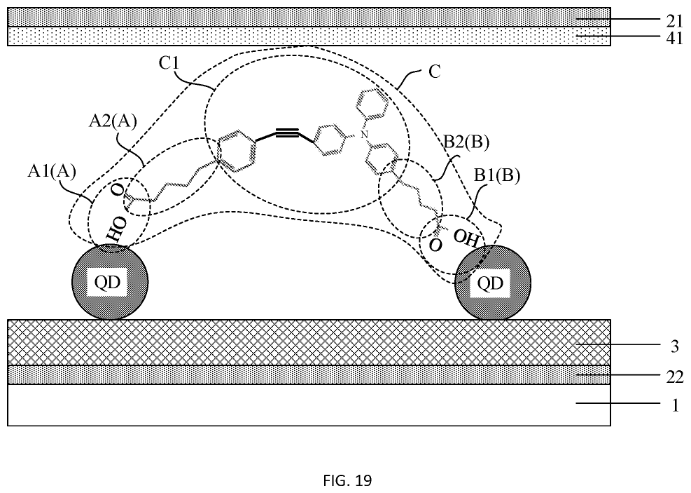

Based on the same inventive concept, embodiments of the present disclosure further provide a light-emitting device. With reference to FIG. 14, FIG. 15, FIG. 16, FIG. 17, FIG. 18 and FIG. 19, the light-emitting device includes: a base substrate 1, an anode 21, a quantum dot layer 3 and a cathode 22. The anode 21, the quantum dot layer 3 and the cathode 22 are stacked on one side of the base substrate. The quantum dot layer 3 includes a plurality of quantum dot bodies QDs. One side, facing the anode layer 21, of the quantum dot layer 3 is provided with a conjugate C. The conjugate C includes: a coupling structure C1, a first connection structure A2 connected to one side of the coupling structure C1, a first coordination group A1 connected to the first connection structure A2 and a quantum dot body QD, a second connection structure B2 connected to the other side of the coupling structure C1, and a second coordination group B1 connected to the second connection structure B2 and a quantum dot body QD. In particular, the quantum dot bodies QDs connected on both sides of the conjugate C may be the same quantum dot body QD, or may be different quantum dot bodies QDs. In particular, the first connection structure A2 and the second connection structure B2 may be the same structure, or may be different structures. The first coordination group A1 and the second coordination group B1 may be the same group or may be different groups.

Specifically, according to the light-emitting device provided by the embodiments of the present disclosure, the quantum dot layer 3 can be formed by coupling of the first ligand A and the second ligand B in the quantum dots provided by the embodiments of the present disclosure.

Specifically, the light-emitting device provided by the embodiments of the present disclosure may be of an upright structure. As shown in FIG. 14, FIG. 15 and FIG. 16, a light-emitting layer 3 is located on one side, facing away from the base substrate 1, of the anode layer 21, and the cathode layer 22 is located on one side, facing away from the anode layer 21, of the light-emitting layer 3. In particular, the light-emitting device provided by the embodiments of the present disclosure may also be of an inverted structure. As shown in FIG. 17, FIG. 18 and FIG. 19, the light-emitting layer 3 is located on one side, facing away from the base substrate 1, of the cathode layer 22, and the anode layer 21 is located on one side, facing away from the cathode layer 22, of the light-emitting layer 3.

In possible embodiments, the coupling structure C1 includes one of:

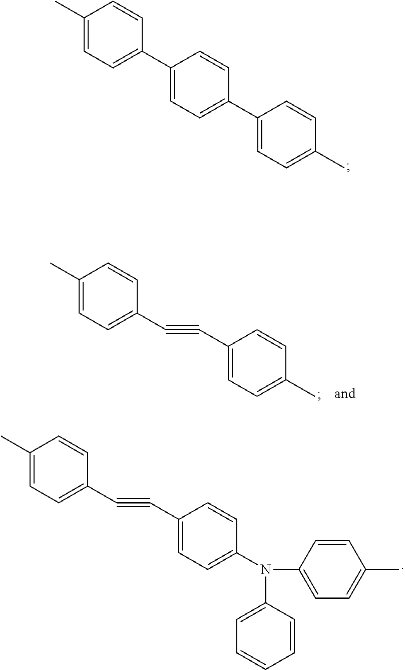

In possible embodiments, the quantum dot layer 3 may further include a first ligand A, and in a direction from the anode layer 21 to the quantum dot layer 3, the content of the conjugate C gradually decreases, and the content of the first ligand A gradually increases. In the embodiments of the present disclosure, the quantum dot layer 3 may also include the first ligand A that does not fully participate in the reaction. In the direction from the anode layer 21 to the quantum dot layer 3, that is, from the surface to the inside of the quantum dot layer 3, the content of the conjugate C gradually decreases, and the content of the first ligand A gradually increases, so that a structure in which an energy level changes gradiently from the outside to the inside is formed on the surface of the side, facing the anode layer 21, of the quantum dot layer 3, which is conducive to hole transport.

In possible embodiments, the quantum dot layer 3 further includes a second ligand B, and in the direction from the anode layer 21 to the quantum dot layer 3, the content of the second ligand B gradually increases.

In possible embodiments, as shown in FIGS. 10 and 14 to 19, a hole transport layer 41 is also disposed between the anode layer 21 and the quantum dot layer 3. A HOMO energy level of the conjugate C is between a HOMO energy level of the hole transport layer 41 and a HOMO energy level of the quantum dot layer 3.

In particular, a hole injection layer may also be disposed between the hole transport layer and the anode layer, an electron transport layer may also be disposed between the light-emitting layer and the cathode layer, and an electron injection layer may also be disposed between the electron transport layer and the cathode layer.

In possible embodiments, a material of the hole transport layer 41 includes nickel oxide or tungsten oxide.

In particular, in a quantum dot light-emitting device, the material of the hole transport layer and the corresponding ligands may be in the following cases.
1. the hole transport layer is NiO nanoparticles, a quantum dot ligand contains aromatic halides A and B, and a conjugated interface product C is formed by nickel catalysis.
2. the hole transport layer is NiO nanoparticles, the quantum dot ligand contains an aromatic halide A, and a conjugated interface product C is formed by nickel-catalyzed self-coupling.
3. the hole transport layer is NiO nanoparticles, the quantum dot ligand contains an aromatic halide A and an aromatic alkyne B, and a conjugated interface product C is formed by nickel catalysis.
4. the hole transport layer is nickel-free oxide nanoparticles (tungsten oxide), the quantum dot ligand contains an aromatic halide A and an aromatic alkyne B, the surface of the shell layer contains copper ions, and a conjugated interface product C is formed by copper catalysis.
5. the hole transport layer is nickel-free oxide nanoparticles (tungsten oxide), the quantum dot ligand contains aromatic halides A and B, the surface of the shell layer contains copper ions, and a conjugated interface product C is formed by copper catalysis.
6. the hole transport layer is nickel-free oxide nanoparticles (tungsten oxide), the quantum dot ligand contains an aromatic halide A, the surface of the shell layer contains copper ions, and a conjugated interface product C is formed by copper-catalyzed self-coupling.

Embodiments of the present disclosure further provide a display apparatus, including a plurality of the light-emitting devices provided by the embodiments of the present disclosure.

In possible embodiments, the plurality of the light-emitting devices include a red light-emitting device, a green light-emitting device, and a blue light-emitting device. The red light-emitting device, the green light-emitting device, and the blue light-emitting device share the same hole transport layer.

In possible embodiments, conjugates of the light-emitting devices of different light emission colors are different. For example, a conjugate of the red light-emitting device may be different from a conjugate of the green light-emitting device, the conjugate of the red light-emitting device may be different from a conjugate of the blue light-emitting device, and the conjugate of the green light-emitting device may be different from the conjugate of the blue light-emitting device.

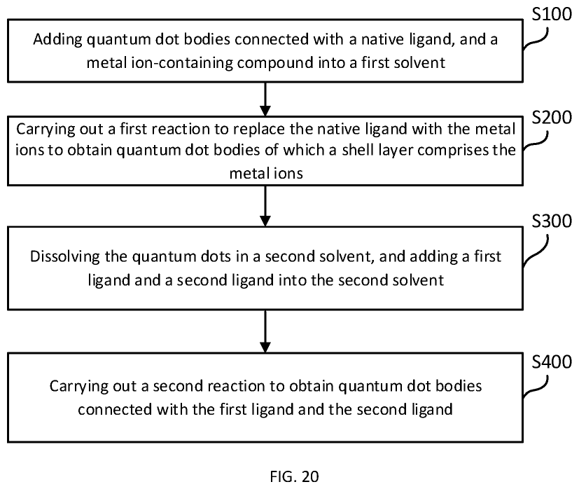

Based on the same inventive concept, referring to FIG. 20, embodiments of the present disclosure further provide a manufacturing method for a quantum dot material, including the following steps.

Step S100, adding a quantum dot bodies body with a native ligand, and a metal ion-containing compound into a first solvent; in particular, the first solvent may be octadecene, the native ligand may be oleic acid, and the metal ion-containing compound may be copper chloride.

Step S200, carrying out a first reaction to replace the native ligand with the metal ions to obtain a quantum dot body of which a shell layer includes the metal ions.

Step S300, dissolving the quantum dot in a second solvent, and adding a first ligand and a second ligand into the second solvent; for example, the second solvent may be toluene.

Step S400, carrying out a second reaction to obtain a quantum dot body connected with the first ligand and the second ligand.

The quantum dot, the light-emitting device, the display apparatus and the manufacturing method provided by the embodiments of the present disclosure are illustrated below by embodiments.

In possible embodiments, the quantum dot contain a ligand A11 and a ligand B11 (as shown in FIG. 11), and copper catalysis is adopted.

1. red/green/blue quantum dots containing copper ions are prepared by ion exchange.

30 mg of red/green/blue quantum dots, a ligand being oleic acid, and 5 mg of copper chloride are dissolved in 5 ml of octadecene. Heating is performed to 150° C. and a reaction is carried out for 20 minutes for completing ligand exchange. The resulting reaction solution is precipitated in 50 ml of methanol. Centrifugation is performed so that a supernatant is removed to obtain quantum dots of which a shell layer contains copper ions. Precipitation and centrifugation are repeated, and the quantum dots are washed for three times, and dissolved in toluene to form a 15 mg/ml solution for standby application. For example, a material of the quantum dot body may include, but is not limited to, CdS, CdSe, ZnSe, InP, PbS, CsPbCl₃, CsPbBr₃, CsPhl₃, CdS/ZnS, CdSe/ZnS, ZnSe, InP/ZnS, PbS/ZnS, CsPbCl₃/ZnS, CsPbBr₃/ZnS, and CsPhl₃/ZnS.

2. red/green/blue quantum dots containing the ligand A11 and the ligand B11 are prepared by ligand exchange.

1 mL of the quantum dot toluene solution formed in the step 1 is mixed with 50 mg of a ligand A11 and 50 mg of a ligand B11 for ligand exchange. The quantum dots are precipitated in methanol after a reaction for 4 hours. Centrifugation is performed so that a supernatant is removed to obtain quantum dots. Precipitation and centrifugation are repeated, and the quantum dots are washed for three times, and dissolved in cyclohexylbenzene to form a 15 mg/ml solution for standby application.

3. a hole injection layer (a material of which may be poly(3,4-ethylenedioxythiophene)-poly(styrenesulfonate), PEDOT: PSS) is spin-coated on a base substrate containing an anode layer (a material of which may be indium tin oxide) in air (spin coating may be performed at 4000 rpm for 30 s), and annealing is performed at 230° C. for 20 minutes. A hole transport layer (a material of which may be a WO3 nanoparticle solution) is spin-coated in a glove box (spin coating may be performed at 3000 rpm for 30 s), and annealing is performed at 150° C. for 15 min. The toluene solution of red quantum dots prepared in the step 2 is deposited by means of inkjet printing. Vacuumizing is performed under a pressure of 1 mbar for 30 min after the completion of deposition, and annealing is performed at 120° C. for 20 min. The green and blue quantum dots are sequentially printed and silenced by post-processing according to the same process. A zinc oxide nanoparticle solution is spin-coated (2000 rpm, 30 s), and annealing is performed at 120° C. for 20 min. An aluminum electrode of 120 nm is evaporated, and encapsulation is performed for completing device manufacture.

In possible embodiments, quantum dots contain a ligand A21 and a ligand B21 (as shown in FIG. 12), and copper catalysis is adopted.

1. red/green/blue quantum dots containing copper ions are prepared by ion exchange.

30 mg of red/green/blue quantum dots, a ligand being oleic acid, and 5 mg of copper chloride are dissolved in 5 ml of octadecene. Heating is performed to 150° C., and a reaction is carried out for 20 minutes for completing ligand exchange. The resulting reaction solution is precipitated in 50 ml of methanol. Centrifugation is performed so that a supernatant is removed to obtain quantum dots of which a shell layer contains copper ions. Precipitation and centrifugation are repeated, and the quantum dots are washed for three times, and dissolved in toluene to form a 15 mg/ml solution for standby application. For example, a material of the quantum dot body may include, but is not limited to, CdS, CdSe, ZnSe, InP, PbS, CsPbCl₃, CsPbBr₃, CsPhl₃, CdS/ZnS, CdSe/ZnS, ZnSe, InP/ZnS, PbS/ZnS, CsPbCl₃/ZnS, CsPbBr₃/ZnS, and CsPhl₃/ZnS.

2. red/green/blue quantum dots containing the ligand A21 and the ligand B21 are prepared by ligand exchange.

1 ml of the quantum dot toluene solution formed in the step 1 is mixed with 50 mg of the ligand A21 and 50 mg of the ligand B21 for ligand exchange. The quantum dots are precipitated in methanol after a reaction for 4 hours. Centrifugation is performed so that a supernatant is removed to obtain quantum dots. Precipitation and centrifugation are repeated, and the quantum dots are washed for three times, and dissolved in cyclohexylbenzene to form a 15 mg/ml solution for standby application.

3. a hole injection layer (a material of which may be poly(3,4-ethylenedioxythiophene)-poly(styrenesulfonate), PEDOT: PSS) is spin-coated on a base substrate containing an anode layer (a material of which may be indium tin oxide) in air (spin coating may be performed at 4000 rpm for 30 s), and annealing is performed at 230° C. for 20 minutes. A hole transport layer (a material of which may be a WO3 nanoparticle solution) is spin-coated in a glove box (spin coating may be performed at 3000 rpm for 30 s), and annealing is performed at 150° C. for 15 min. The toluene solution of red quantum dots prepared in the step 2 is deposited by means of inkjet printing, vacuumizing is performed under a pressure of 1 mbar for 30 min after the completion of deposition, and annealing is performed at 120° C. for 20 min. The green and blue quantum dots are sequentially printed and silenced by post-processing according to the same process. A zinc oxide nanoparticle solution is spin-coated (2000 rpm, 30 s), and annealing is performed at 120° C. for 20 min. An aluminum electrode of 120 nm is evaporated, and encapsulation is performed for completing device manufacture.

In possible embodiments, quantum dots contain a ligand A31 and a ligand B31 (as shown in FIG. 13), and nickel catalysis is adopted.

1. red/green/blue quantum dots containing the ligand A31 and the ligand B31 are prepared by ligand exchange.

1 mL of the quantum dot toluene solution formed in the step 1 is mixed with 50 mg of the ligand A31 and 50 mg of the ligand B31 for ligand exchange. The quantum dots are precipitated in methanol after a reaction for 4 hours. Centrifugation is performed so that a supernatant is removed to obtain quantum dots. Precipitation and centrifugation are repeated, and the quantum dots are washed for three times, and dissolved in cyclohexylbenzene to form a 15 mg/ml solution for standby application.

2. a hole injection layer (a material of which may be poly(3,4-ethylenedioxythiophene)-poly(styrenesulfonate), PEDOT: PSS) is spin-coated on a base substrate containing an anode layer (a material of which may be indium tin oxide) in air (spin coating may be performed at 4000 rpm for 30 s), and annealing is performed at 230° C. for 20 minutes. A hole transport layer (a material of which may be a NiO nanoparticle solution) is spin-coated in a glove box (spin coating may be performed at 3000 rpm for 30 s), and annealing is performed at 150° C. for 15 min. The toluene solution of red quantum dots prepared in the step 2 is deposited by means of inkjet printing, vacuumizing is performed under a pressure of 1 mbar for 30 min after the completion of deposition, and annealing is performed at 120° C. for 20 min. The green and blue quantum dots are sequentially printed and silenced by post-processing according to the same process. A zinc oxide nanoparticle solution is spin-coated (2000 rpm, 30 s), and annealing is performed at 120° C. for 20 min. An aluminum electrode of 120 nm is evaporated, and encapsulation is performed for completing device manufacture.

Beneficial effects of embodiments of the present disclosure are as follows. In the embodiments of the present disclosure, the quantum dot body QD is connected with the first ligand A and the second ligand B. The first ligand A includes the first coordination group A1, the first connection structure A2, and the first coupling reaction structure A3. The first coupling reaction structure A3 includes the halide. The second ligand B includes: the second coordination group B1 connected to the quantum dot body QD, the second connection structure B2, and the second coupling reaction structure B3. When the quantum dots are applied to a light-emitting device in which an electron transport rate is faster than a hole transport rate, since electron enrichment occurs on the side, facing the anode layer, of the quantum dot layer (e.g., at the interface between the quantum dot layer and the hole transport layer) during the power-on operation of the light-emitting device to form a donor system, a coupling reaction between the first coupling reaction structure A3 and the second coupling reaction structure B3 at the interface is promoted. The coupling reaction couples at least two ligands together to form a product with a greater conjugation degree at the interface. A HOMO energy level at the interface increases due to the increase of the degree of conjugation, playing a role in adding an intermediate barrier on the side, facing the anode layer, of the quantum dot layer (for example, between barriers of the hole transport layer and the quantum dot film layer), thereby facilitating efficient injection of holes into the quantum dot layer and balancing the injection of electrons and holes.

Obviously, those skilled in the art can make various modifications and variations to the present disclosure without departing from the spirit and scope of the present disclosure. Thus, if these modifications and variations of the present disclosure fall within the scope of the claims of the present disclosure and their equivalents, the present disclosure is also intended to include these modifications and variations.

1. A quantum dot material, comprising:
a plurality of quantum dot bodies;
a first ligand, wherein the first ligand is connected to the quantum dot body and comprises: a first coordination group connected to the quantum dot body, a first connection structure, and a first coupling reaction structure, the first connection structure connects the first coordination group with the first coupling reaction structure, and the first coupling reaction structure comprises a halide; and
a second ligand, wherein the second ligand is connected to the quantum dot body and comprises: a second coordination group connected to the quantum dot body, a second connection structure, and a second coupling reaction structure, and the second connection structure connects the second coordination group with the second coupling reaction structure.

2. The quantum dot material according to claim 1, wherein the first coupling reaction structure comprises: an aromatic halide, and the second coupling reaction structure comprises: an aromatic halide, an aromatic alkyne, an alternating single bond-double bond structure, an alternating single bond-triple bond structure, or an alternating triple bond-single bond-double bond structure.

3. The quantum dot material according to claim 1, wherein the first coordination group comprises: amino, sulfhydryl, carboxyl, phosphoxy, or hydroxyl; and the second coordination group comprises amino, sulfhydryl, carboxyl, phosphoxy, or hydroxyl.

4. The quantum dot material according to claim 3, wherein the first connecting structure comprises a linear carbon chain or a branched carbon chain; and the second connection structure comprises a linear carbon chain or a branched carbon chain.

5. The quantum dot material according to claim 1, wherein the first ligand comprises one of: 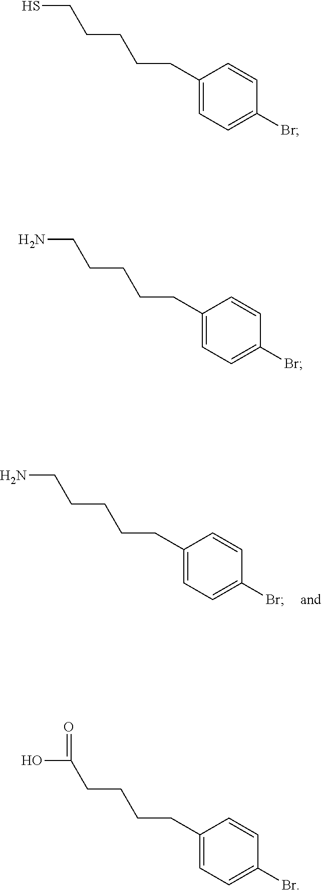 [SMILES: SCCCCCc1ccc(Br)cc1 ; NCCCCCc1ccc(Br)cc1 ; NCCCCCc1ccc(Br)cc1 ; O=C(O)CCCCc1ccc(Br)cc1]
and
the second ligand comprises one of:

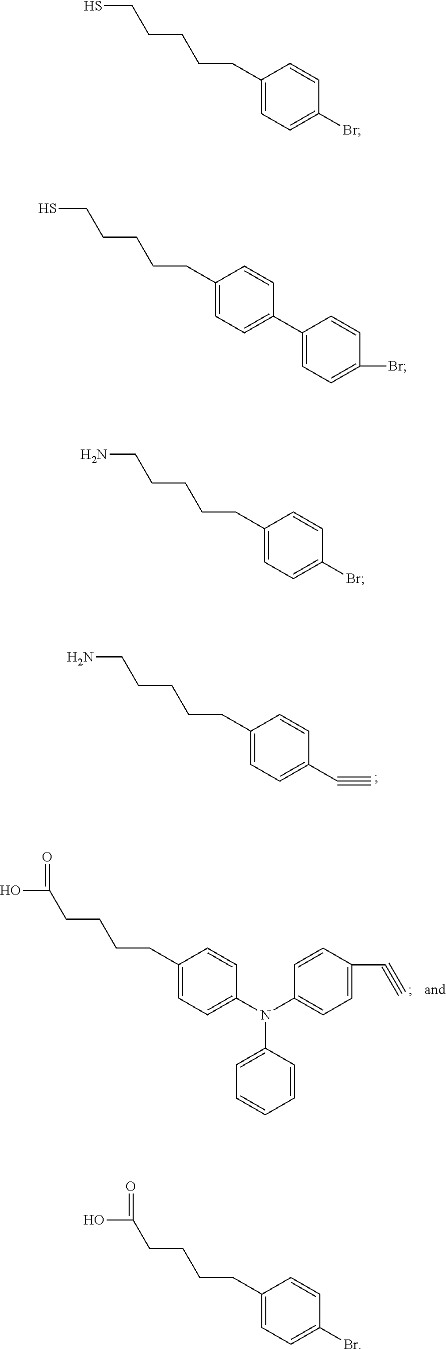 [SMILES: SCCCCCc1ccc(Br)cc1 ; SCCCCCc1ccc(-c2ccc(Br)cc2)cc1 ; NCCCCCc1ccc(Br)cc1 ; C#Cc1ccc(CCCCCN)cc1 ; C#Cc1ccc(N(c2ccccc2)c2ccc(CCCCC(=O)O)cc2)cc1 ; O=C(O)CCCCc1ccc(Br)cc1]

6. The quantum dot material according to claim 1, wherein the quantum dot body comprises a core portion, and a shell layer located on at least part of a surface of the core portion, the shell layer comprising nickel or copper.

7. A light-emitting device, comprising: a base substrate, an anode, a quantum dot layer and a cathode, wherein the anode, the quantum dot layer and the cathode are stacked on one side of the base substrate; the quantum dot layer comprises a plurality of quantum dot bodies, and one side, facing the anode layer, of the quantum dot layer is provided with a conjugate; and
the conjugate comprises: a coupling structure, a first connection structure connected to one side of the coupling structure, a first coordination group being connected to the first connection structure and the quantum dot body, a second connection structure connected to the other side of the coupling structure, and a second coordination group being connected to the second connection structure and the quantum dot body.

8. The light-emitting device according to claim 7, wherein the coupling structure comprises one of:

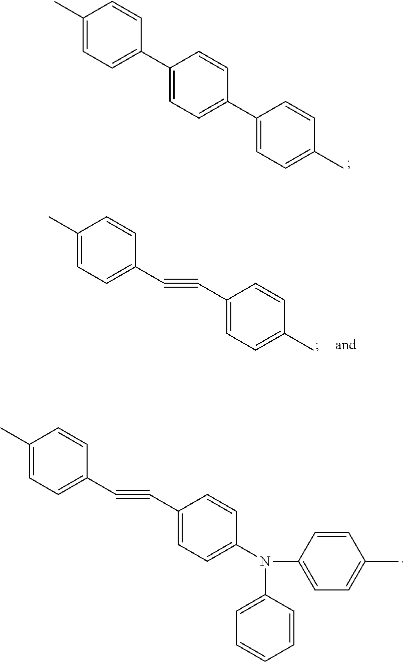

9. The light-emitting device according to claim 7, wherein the quantum dot layer further comprises a first ligand, and in a direction from the anode layer to the quantum dot layer, content of the conjugate gradually decreases, and content of the first ligand gradually increases.

10. The light-emitting device according to claim 9, wherein the quantum dot layer further comprises a second ligand, and in the direction from the anode layer to the quantum dot layer, content of the second ligand gradually increases.

11. The light-emitting device according to claim 7, wherein a hole transport layer is disposed between the anode layer and the quantum dot layer; and a HOMO energy level of the conjugate is between a HOMO energy level of the hole transport layer and a HOMO energy level of the quantum dot layer.

12. The light-emitting device according to claim 11, wherein a material of the hole transport layer comprises nickel oxide or tungsten oxide.

13. A display apparatus, comprising a plurality of the light-emitting devices according to claim 7.

14. The display apparatus according to claim 13, wherein the plurality of the light-emitting devices comprise different sub-pixel light-emitting devices; and the different sub-pixel light-emitting devices share the same hole transport layer.

15. The display apparatus according to claim 14, wherein the conjugates of the different sub-pixel light-emitting devices are different.

16. A manufacturing method for a quantum dot material, comprising:
adding quantum dot bodies connected with a native ligand, and a compound containing metal ions into a first solvent;
carrying out a first reaction to replace the native ligand with the metal ions to obtain quantum dot bodies of which a shell layer comprises the metal ions;
dissolving the obtained quantum dot bodies in a second solvent, and adding a first ligand and a second ligand into the second solvent; and
carrying out a second reaction to obtain quantum dot bodies connected with the first ligand and the second ligand.
